(19) United States
(12) Patent Application Publication
(10) Pub. No.: US 2004/0087155 A1
(43) Pub. Date: May 6, 2004

(54) Method of removing sidewall spacers in the fabrication of a semiconductor device using an improved removal process

(76) Inventors: Karsten Wieczorek, Dresden (DE); Manfred Horstmann, Dresden (DE); Rolf Stephan, Dresden (DE)

Correspondence Address: J. Mike Amerson, Williams, Morgan & Amerson, P.C., Suite 1100, 10333 Richmond, Houston, TX, 77042, US

(21) Appl. No.: 10/621,662

(22) Filed: Jul. 17, 2003

(30) Foreign Application Priority Data
Oct. 31, 2002 (DE) 102 50 899.2

(51) Int. Cl. H01L 21/302; H01L 21/461

(52) U.S. Cl. 438/689

(57) ABSTRACT

A method for improving the etch behavior of sidewall spacers in the fabrication of a CMOS device is disclosed. The etch rate of the material of the sidewall spacers depends on the implantation conditions. Thus, the etch rates are different for N-type and P-type transistors. To remove the sidewall spacers properly, the etch rates are altered by an implantation of ions, thereby modifying the structure of the material of the sidewall spacers and increasing the etch rate of the material. The increased etch rate leads to a shorter process time in the spacer removal process. Thus, the surrounding regions are less affected by the removal process and the device reliability and performance is improved.

### BACKGROUND OF THE INVENTION

1. Field of the Invention

The present invention relates to the field of fabrication of integrated circuits, and, more particularly, to a method for improving the etch behavior of sidewall spacers of a semiconductor device.

2. Description of the Related Art

The trend towards an increasing integration density of integrated circuits leads to a further miniaturization of the semiconductor devices of the integrated circuits. The associated shrinkage of device features generates numerous serious challenges for semiconductor manufacturers to provide the devices with the desired electrical characteristics and geometric structures, also referred to as critical dimensions (CD). Particularly, the formation of the gate electrode, with the required shape and with a size in the currently focused sub-100 nm range, is rather crucial. In devices having such small feature sizes, the unavoidable diffusion of ions, particularly driven by the required annealing processes during device fabrication, becomes a concern. For example, the lateral diffusion of the ions implanted into the lightly doped drain (LDD) regions leads to an undesired LDD/gate overlap. The LDD/gate overlap increases the Miller (gate/drain) capacitance, which affects the device switching characteristic and consequently deteriorates the device performance.

The Miller capacitance may be reduced by altering the sequence of the device fabrication process, so that the deep source/drain implantation and annealing are performed prior to the LDD implantation. Thus, the deep source/drain annealing may be carried out without affecting the diffusion of the LDD ions. Implanting the source/drain region prior to the LDD region, however, requires removal of the sidewall spacers employed to define the deep source/drain region after the deep source/drain implantation process is completed. The sidewall spacers are typically formed of silicon nitride (SiN) and may be removed by the use of hot phosphoric acid (H₃PO₄). The silicon nitride to silicon etch selectivity of hot phosphoric acid, however, is poor, particularly when the silicon is pre-doped. The low selectivity causes undesired erosion in regions of the device in the spacer removal process. Thus, controlling critical dimensions becomes more difficult. The etch selectivity may be improved by forming a thin thermal oxide layer (liner oxide) on the gate electrode of the semiconductor device prior to the formation of the sidewall spacers. Particularly in CMOS devices, however, the spacer removal process is a concern even when a liner oxide is employed.

To explain in detail the use of sidewall spacers according to a typical prior art process sequence with disposable spacers and a liner oxide, the corresponding process flow for forming a MOS field effect transistor is described with reference to FIGS. 1a-1d.

FIG. 1a schematically depicts a semiconductor device structure 1 comprising a silicon substrate 10, shallow trench isolation regions 20, a gate insulation layer 31 and a gate electrode 41. A typical process flow for forming the semiconductor structure 1 includes well-known lithography, etch and deposition techniques and, thus, a description thereof will be omitted.

FIG. 1b depicts the semiconductor device structure 1 after the formation of sidewall spacers 81 on a liner oxide 85 and during a deep source/drain implantation process 75 resulting in deep source/drain regions 72. The liner oxide 85 is grown in a thermal oxidation process. Subsequently, the sidewall spacers 81 are formed in an anisotropic etch process, typically in a plasma etch process, from a blanket deposited silicon nitride layer. Subsequently, the implantation process 75 to form the deep source/drain regions 72 is performed, prior to the implantation of LDD regions still to be formed. To activate the implanted ions, a deep source/drain rapid thermal annealing (RTA) process is carried out at a high temperature causing a high diffusivity. Since the LDD regions are not yet implanted, the deep source/drain region annealing process may not cause an undesired LDD/gate overlap.

The silicon nitride sidewall spacers 81 may be covered with a thin silicon oxide layer (not shown), particularly when the annealing process takes place in an oxygen-containing ambient. The thin silicon oxide layer grows in a slow and self-limiting process by conversion of nitride to oxide.

FIG. 1c depicts the semiconductor device structure 1 after the removal of the sidewall spacers 81. The silicon oxide layer that may cover the sidewall spacers is removed in a hydrogen fluoride, (HF) dip process. The silicon nitride sidewall spacers 81 are typically removed by the use of hot phosphoric acid (H₃PO₄). The silicon nitride to silicon oxide etch selectivity of hot phosphoric acid, however, is too low, particularly when the silicon oxide structure is modified by the prior deep source/drain implantation and, hence, the liner oxide 85 may not resist the hot phosphoric acid etching in the spacer removal process. Thus, erosion of the thin liner oxide 85 and even erosion of the underlying silicon gate electrode 41 may occur. Such erosion may also occur in the deep source/drain regions 72 where the silicon is heavily doped and consequently, due to the higher etch rate, the etch selectivity is deteriorated. On the other hand, shortening the etch process time may cause an incomplete removal of the silicon nitride sidewall spacers 81. Furthermore, the etch rate of silicon nitride is also affected by the pre-doping conditions. Thus, the sidewall spacers 81 of N-type and P-type MOSFETs may have a different etch rate in phosphoric acid due to the different dopant concentration.

FIG. 1d depicts the semiconductor device structure 1 after the removal of the liner oxide 85: and during an LDD implantation process 76 for forming LDD regions 71. The LDD implantation 76 is performed in a known conventional implantation process. The liner oxide 85 may be removed prior to the LDD implantation process 76 by well-known wet chemical etch processes or may be employed as a screen oxide. The subsequent rapid thermal annealing process may be advantageously optimized for the required activation of the LDD regions 71, whereby concurrently the lateral diffusion may be avoided or at least reduced. The diffusivity may be reduced compared to an annealing process required when the deep source/drain regions 72 and the LDD regions 71 have to be annealed in a single process. Thus, lateral diffusion of the LDD ions under the gate electrode 41 (LDD/gate overlap) is reduced and consequently the undesired parasitic capacitances are also decreased and the device performance is improved.

FIG. 1e depicts the semiconductor device structure 1 after the formation of sidewall spacers 82 and silicide regions 91. The newly formed sidewall spacers 82 are required to protect the extension of LDD regions 71 in the subsequent silicide process. The silicide regions 91 are formed in a conventional self-aligned silicide process. The silicide process may, for example, be performed by blanket depositing a layer of refractory metal and by a subsequent two-step thermal annealing process, wherein non-reacted excess metal is removed by an appropriate etch process after the first anneal step.

The different etch rates of sidewall spacers of N-type and P-type MOSFETs in phosphoric acid make it more difficult to remove the sidewall spacers in CMOS devices without over-etching and/or leaving spacer residuals. The etch rate of the sidewall spacers depends on the implant parameter of the deep source/drain implantation 75, such as implant species, energies and doses. For P-type transistors, typically boron is implanted at an ion energy range of approximately 5-45 keV and with a dose of up to approximately 2×10¹⁵ ions/cm² is employed. For N-type transistors, typically the heavier arsenic or phosphorus ions having an energy in the same energy range and with a dose of up to approximately 2×1015-6×1015 are used. Thus, the sidewall spacers of N-type transistors show a higher etch rate than the P-type transistors. Failures that may arise from the different dopant concentration and the different doping conditions in the spacer removal process in CMOS devices are illustrated in FIGS. 2a to 2c.

FIG. 2a schematically depicts a cross-sectional view of a CMOS device structure 2 prior to the removal of sidewall spacers 81. The structure includes an N-type and a P-type field effect transistor formed on a silicon substrate 10 and separated by shallow trench isolation regions 20. The transistors comprise a gate insulation layer 31, a gate electrode 41, a liner oxide 85, N-type or P-type deep source/drain regions 72 and the sidewall spacers 81, which may be covered with a thin silicon oxide layer 86.

The field effect transistors are formed as described with respect to FIG. 1b for a single transistor, wherein the same reference signs are used to denote similar or identical components or parts.

FIG. 2b schematically depicts the result of an etch process adapted to etch the sidewall spacers 81 of the N-type transistor of the CMOS structure 2. The sidewall spacers 81 of the N-type transistor are substantially completely removed, whereas the removal of the sidewall spacers 81 of the P-type transistor is incomplete and may leave behind residual spacer material 83 that may cause a non-uniform LDD implantation 76 (shown in FIG. 1d).

FIG. 2c contrary thereto depicts the result of an etch process appropriate to etch the sidewall spacers 81 of the P-type transistor of the CMOS structure 2. In this case, the sidewall spacers 81 of the P-type transistor are substantially completely removed, whereas, however, the removal of the sidewall spacers 81 of the N-type transistor may cause undue over-etching, leading to over-etching of the liner oxide 85 and even of the silicon of the gate electrode 41 and of the deep source/drain regions 72.

In view of the problems pointed out above, there is a need to adjust the etch rates of sidewall spacers of N-type and/or P-type transistors to enhance uniformity during the removal of spacers of the transistors.

### SUMMARY OF THE INVENTION

According to the present invention, a method is provided wherein disposable sidewall spacers of a semiconductor device are irradiated by ions to modify the structure of the material of the sidewall spacers in order to enhance the etch rate of the sidewall spacers and to consequently increase the etch selectivity in the corresponding removal process.

According to one illustrative embodiment of the present invention, a method of removing sidewall spacers of a semiconductor structure comprises providing a substrate having partially formed thereon semiconductor devices, wherein the devices comprise first and second sidewall spacers with a first and second etch rate to a specific etchant, whereby the first etch rate is lower than the second etch rate. The method further comprises implanting ions into the first sidewall spacers to adapt the first etch rate to the second etch rate. Furthermore, the method comprises removing the first and second sidewall spacers with the specific etchant, whereby a selectivity in removing the first and second sidewall spacers is increased by the implantation of ions.

According to another illustrative embodiment of the present invention, a method of removing sidewall spacers of a semiconductor structure comprises providing a substrate having partially formed thereon semiconductor devices, wherein the devices comprise first and second sidewall spacers with a first and a second etch rate to a specific etchant, whereby the first etch rate is lower than the second etch rate. The method further comprises implanting ions into the first and second sidewall spacers to increase the first and second etch rates, and removing the sidewall spacers with the specific etchant, whereby a selectivity in removing the first and second sidewall spacers is increased by the implantation of ions.

### BRIEF DESCRIPTION OF THE DRAWINGS

The invention may be understood by reference to the following description taken in conjunction with the accompanying drawings, in which like reference numerals identify like elements, and in which:

FIGS. 1a-1e schematically depict a cross-sectional view of a semiconductor device structure, illustrating a typical process flow of the formation of the source/drain regions of a MOS field effect transistor according to the prior art;

FIGS. 2a-2c schematically depict a cross-sectional view of a CMOS device structure illustrating the typical failures occurring in the sidewall spacer removal process in a CMOS device according to the prior art;

FIGS. 3a-3e schematically depict a cross-sectional view of a CMOS device structure illustrating the formation of the source/drain regions of a MOS field effect transistor in accordance with one illustrative embodiment of the present invention;

FIG. 4 schematically depicts a cross-sectional view of a CMOS device structure illustrating a sidewall spacer removal process according to another illustrative embodiment of the present invention; and

FIG. 5 schematically depicts a cross-sectional view of a CMOS device structure illustrating the sidewall spacer removal process for a device without a liner oxide according to yet another embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention includes the concept of balancing or individually adjusting the etch rates of sidewall spacers of field effect transistors, such as N-type and P-type transistors in CMOS devices, to improve the etch removal process of sidewall spacers. The etch rates may be altered by increasing at least the etch rate of the spacers of the P-type field effect transistor. The etch rate is increased by irradiating ions into the sidewall spacers. Irradiating ions into a solid state feature changes the structure of the material of the feature into a more amorphous state, i.e., the short range order in the structure of the material is modified. Particularly heavy ions cause strong damage in the solid structure even at a relatively low dose. In one particular embodiment, inert ions are employed so that the electrical characteristics of the implant regions are minimally affected by implanted ions. Thus, the term “inert ions” is to be understood as referring to ions having only a minimal influence on the electrical behavior of the materials employed to form the device features, and substantially not acting as a dopant in the semiconductor regions. Thus, for example, argon, xenon, krypton, and the like may be used as inert ions. For silicon-based or germanium-based device features, silicon or germanium ions, respectively, may be considered as “inert ions.” On the other hand, implanted semiconductor ions of a different species, for example, germanium ions in a silicon-based device, may alter the device characteristic, and may thus be concurrently employed, for example, for band gap engineering purposes.

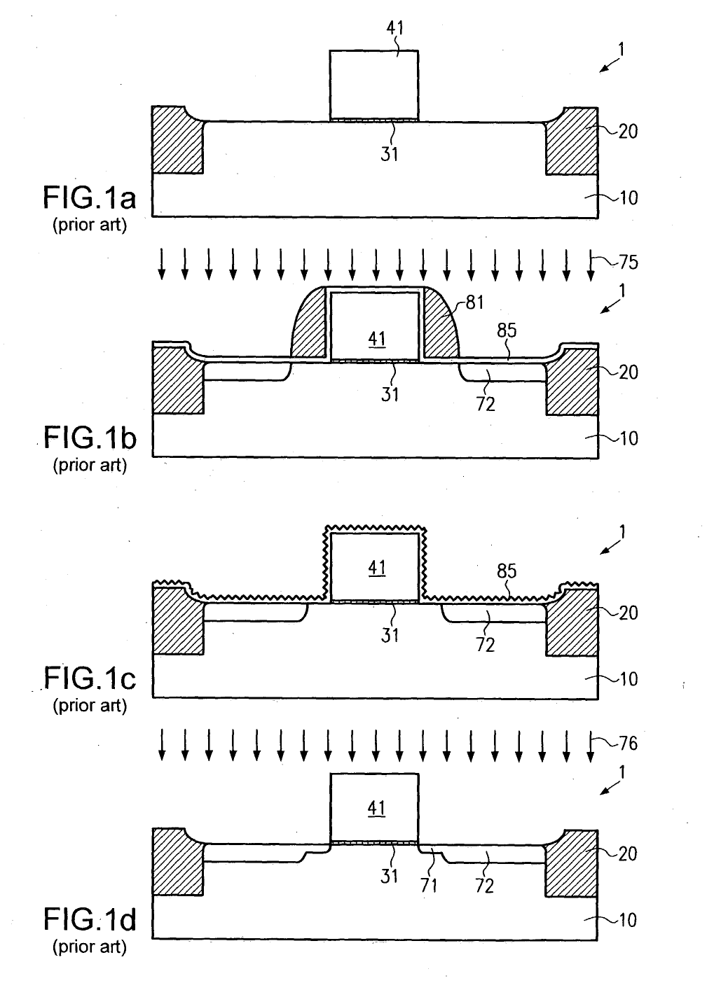

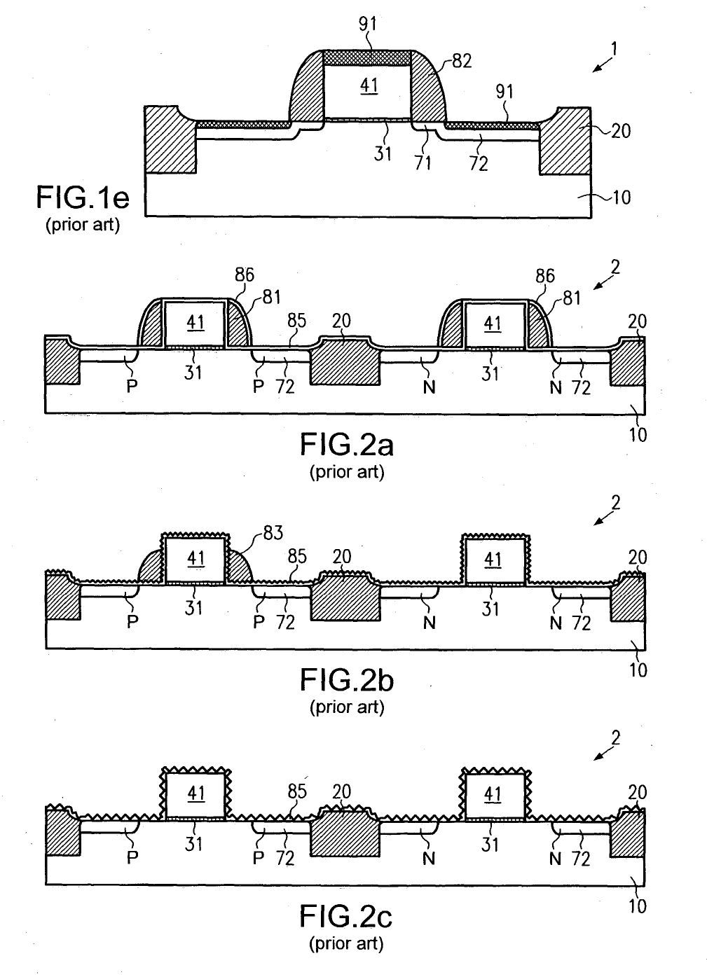

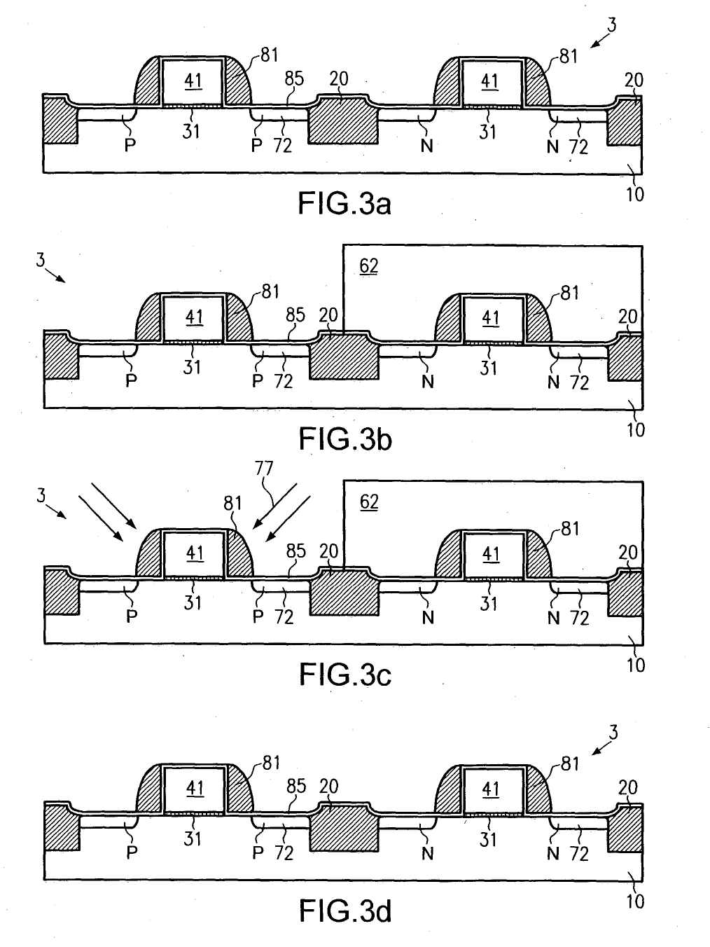

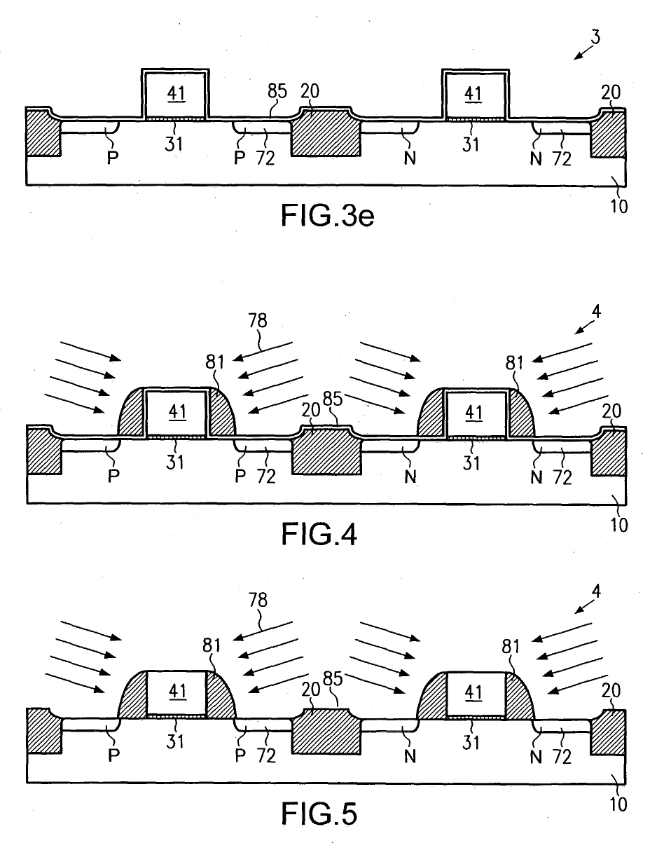

With reference to FIGS. 3a-3e, 4 and 5, illustrative embodiments according to the present invention will now be described. In FIGS. 3a-3e, 4 and 5, the same reference signs as in FIGS. 1a-1e and 2a-2c are used to denote similar or equal components and parts.

The embodiments illustrated in FIGS. 3a-3e, 4 and 5 relate to a field effect transistor device formed on a silicon substrate 10 and comprising a polysilicon gate device feature 41. The substrate employed, however, is not limited to a silicon substrate, and any other substrate, for example, a germanium substrate or a silicon on insulator (SOI) substrate, may be used. Further, the employed device is not limited to a field effect transistor and any other feature having a sidewall may be employed. Moreover, the device feature 41 is not limited to a polysilicon gate, and any other gate or interconnect line feature, for example, a metal gate or a polysilicon interconnect line, may be used.

The illustrative embodiments according to the present invention shown in FIGS. 3a-3e employ the same steps as described with respect to FIGS. 1a-1e. Thus, FIGS. 3a-3e schematically depict only the additional process steps improving the removal process in a CMOS device.

FIG. 3a depicts a CMOS structure 3, similar to the structure of FIG. 2a, including an N-type and a P-type field effect transistor formed on the silicon substrate 10 and separated by a shallow trench isolation region 20. The transistors comprise N-type or P-type deep source/drain regions 72, a gate insulation layer 31, the gate electrode 41, a liner oxide 85 and sidewall spacers 81, respectively.

The transistors may be formed in a process according to a prior art process depicted in FIG. 1b and are N- or P-doped to form the CMOS structure 3. The sidewall spacers 81 may comprise an inorganic material, for example, silicon nitride, or may comprise a low-k material, for example, a carbon doped oxide. Low-k materials may reduce parasitic capacitances and may thus increase the device performance and reduce the power consumption of the device.

FIG. 3b depicts the CMOS structure 3 further comprising a mask feature 62. The mask feature 62 may be formed in a photolithography process, whereby the mask feature 62 may be the resist feature itself or, in other embodiments, a hard mask feature formed by means of depositing a layer of material and performing an etching process to define the hard mask. The mask feature thickness depends on the screening effect of the material and the tilt angle of the implantation and may, for a resist mask, be in the range of approximately 100-2000 nm.

FIG. 3c depicts the CMOS structure 3 during a tilted ion implantation process 77. The dose of the tilted ion implantation process 77 is selected to raise the etch rate of the material of the exposed sidewall spacers 81 of the P-type transistor up to a level that it is substantially equal to the etch rate of the material of the sidewall spacer 81 of the masked N-type transistor.

The sidewall spacers 81 are located at sidewalls extending substantially perpendicular to the surface of the substrate 10. Thus, the sidewall spacers 81 are typically more extended in that direction. Hence, the implantation is performed with the substrate 10 being tilted to increase the amount of ions irradiated onto the sidewall spacers 81 and to concurrently reduce the undesired irradiation of the adjacent regions of the device. Particularly high tilt angles are appropriate to improve the ratio of ions implanted into the spacers 81 to ions implanted into the adjacent regions of the device. An implantation at very high tilt angles, however, may suffer from a shielding effect caused by the upper edge of the mask feature 62, since the edge of the mask feature 62 may be located close to the sidewall spacer 81 due to the small distance that N-type and P-type transistors are typically spaced apart in CMOS devices. To compensate the shielding effect, the implantation dose may be increased accordingly to balance the etch rates of the materials of the sidewall spacers 81 of the N-type and P-type transistor. The employed tilt angle for the implantation may range from approximately 10-70 degrees.

FIG. 3d depicts the CMOS structure 3 after the removal of the mask feature 62. The mask may be stripped with well-known etch methods. Residuals of the resist mask feature 62 may be substantially removed with a resist ash method, wherein the residual resist is oxidized in an oxygen-containing plasma. In the cases where a hard mask is employed, an etchant appropriate for the selected hard mask material and having the required selectivity to the adjacent device features is used to remove the mask feature 62.

FIG. 3e depicts the CMOS structure 3 after the removal of the sidewall spacers 81. The thin silicon oxide layer (not shown) that may cover the sidewall spacers 81 is removed in a hydrogen fluoride (HF) dip process according to the prior art, however, the process time is reduced, due to the increased etch rate caused by the ion implantation.

Due to the substantially balanced etch rates, the sidewall spacers 81 of the N-type and P-type transistor may be removed in a common etch step, thereby leaving less residuals of spacer materials and causing less etching of the liner oxide 85.

In another embodiment depicted in FIG. 4, the CMOS structure 4 of FIG. 3a is irradiated with ions without forming the mask feature 62. Thus, the mask feature 62 may not shield the ion radiation and a higher tilt angle of the substrate in the range of approximately 10-85 degrees may be employed. Therefore, the ratio of ions implanted into the sidewall spacers 81 to ions implanted into the adjacent regions of the CMOS device is increased. Due to the increased ratio, the dose of ions irradiated on the substrate 10 may be increased without unduly affecting the characteristic of the CMOS device. Thus, mainly the etch rate of the sidewall spacers 81 is increased and, hence, the etch selectivity is improved. Concurrently, the high dose implantation into both the sidewall spacers 81 of the N-type and P-type transistors may reduce the etch rate differences of the materials of the sidewall spacers 81 of both transistor types. Thus, the sidewall spacers 81 of the N-type and P-type transistor may also be removed in a common etch step, thereby leaving less residuals and causing less etching of the liner oxide 85.

FIG. 5 depicts yet another embodiment, wherein the liner oxide 85 may be omitted due to the improved etch selectivity and the increased etch rate. Although the etch selectivity of silicon nitride to silicon of hot phosphoric acid is lower than that of silicon nitride to silicon oxide, it may be sufficient to remove the sidewall spacers 81 without unduly affecting the adjacent silicon even in the pre-doped regions, such as the gate electrode 41 and the deep source/drain regions 72.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of removing sidewall spacers of a semiconductor structure, the method comprising:
providing a substrate having partially formed thereon semiconductor devices, the devices comprising first and second sidewall spacers with first and second etch rates with respect to a specific etchant, whereby said first etch rate is lower than said second etch rate;
implanting ions into said first sidewall spacers to adapt said first etch rate to said second etch rate; and
removing said first and second sidewall spacers with the specific etchant, whereby a selectivity in removing said first and second sidewall spacers is increased by the implanting of said ions.

2. The method of claim 1, wherein said partially formed semiconductor devices are partially formed N-type and P-type field effect transistors.

3. The method of claim 1, wherein said semiconductor structure is a CMOS structure.

4. The method of claim 1, wherein a mask covering at least said second sidewall spacers is employed to implant said ions into said first sidewall spacers.

5. The method of claim 4, wherein said mask is formed by photolithography.

6. The method of claim 4, wherein said mask is one of a photoresist mask and a hard mask.

7. The method of claim 6, wherein said photoresist mask has a thickness of approximately 100-2000 nm

8. The method of claim 1, wherein said ions are substantially inert ions.

9. The method of claim 1, wherein said ions are at least one of argon ions, xenon ions, germanium ions and silicon ions.

10. The method of claim 1, wherein the ion implant dose is in the range of approximately 1×10¹³ to 1×10^{l5} ions/cm².

11. The method of claim 1, wherein the ion energy is in the range of approximately 10-80 keV.

12. The method of claim 1, wherein a tilt angle between a surface of said substrate and a direction of incidence of said ions is in the range of approximately 10-70 degrees.

13. The method of claim 1, wherein the material of said sidewall spacers comprises an inorganic material.

14. The method of claim 1, wherein the material of said sidewall spacers comprises a low-k material.

15. The method of claim 1, wherein the material of said sidewall spacers is silicon nitride.

16. The method of claim 1, wherein, prior to the step of implanting ions into said sidewall spacers, dopants are implanted into said sidewall spacers during the formation of a source and a drain region in said partially formed semiconductor device.

17. The method of claim 16, wherein said dopants are at least one of boron, arsenic and phosphorous.

18. The method of claim 1, wherein said partially formed semiconductor device comprises a gate feature and the measure of said gate feature in one direction is approximately 100 nm or less.

19. A method of removing sidewall spacers of a semiconductor structure, the method comprising:
providing a substrate having partially formed thereon semiconductor devices, the devices comprising first and second sidewall spacers with first and second etch rates to a specific etchant, whereby said first etch rate is lower than said second etch rate;
implanting ions into said first and second sidewall spacers to increase said first and second etch rates; and
removing said first and second sidewall spacers with the specific etchant, whereby a selectivity in removing said first and second sidewall spacers is increased by the implanting of ions.

20. The method of claim 19, wherein said partially formed semiconductor devices are partially formed N-type and P-type field effect transistors.

21. The method of claim 19, wherein said semiconductor structure is a CMOS structure.

22. The method of claim 19, wherein said ions are substantially inert ions.

23. The method of claim 19, wherein said ions are at least one of argon ions, xenon ions, germanium ions and silicon ions.

24. The method of claim 19, wherein the ion dose is in the range of approximately 1×10¹⁴ to 1×10¹⁵ ions/cm².

25. The method of claim 19, wherein the ion energy is in the range of approximately 10-80 keV.

26. The method of claim 19, wherein a tilt angle between a surface of said substrate and a direction of incidence of said ions is in the range of approximately 10-85 degrees.

27. The method of claim 19, wherein the material of said sidewall spacers comprises an inorganic material.

28. The method of claim 19, wherein the material of said sidewall spacers comprises a low-k material.

29. The method of claim 19, wherein the material of said sidewall spacers comprises silicon nitride.

30. The method of claim 19, wherein, prior to said implanting of ions, dopants are implanted into said sidewall spacers during the formation of a source and a drain region.

31. The method of claim 30, wherein said dopants are at least one of boron, arsenic and phosphorous.

32. The method of claim 19, wherein said partially formed semiconductor devices comprise a gate feature and a dimension of said gate feature in at least one direction is 100 nm or less.
